(19) United States
(12) Patent Application Publication
(10) Pub. No.: US 2020/0203351 A1
(43) Pub. Date: Jun. 25, 2020

(54) MEMORY DEVICE

(71) Applicant: Samsung Electronics Co., Ltd., Suwon-si (KR)

(72) Inventors: Kyo-suk CHAE, Suwon-si (KR); Tai-uk RIM, Suwon-si (KR); Hyeon-kyun NOH, Hwaseong-si (KR); Won-sok LEE, Suwon-si (KR)

(21) Appl. No.: 16/563,853

(22) Filed: Sep. 7, 2019

(30) Foreign Application Priority Data
Dec. 20, 2018 (KR) 10-2018-0166412

(51) Int. Cl. H01L 27/108; H01L 29/423; H01L 29/49; H01L 29/40

(52) U.S. Cl. CPC H01L 27/10823; H01L 29/4236; H01L 27/10814; H01L 27/10876; H01L 29/401; H01L 29/4991

(57) ABSTRACT

A memory device includes: a substrate including a first active region and a second active region spaced apart from each other; a device isolation film on the substrate, the device isolation film defining the first active region and the second active region; and a buried word line structure passing a low dielectric region between the first active region and the second active region, wherein the buried word line structure includes a gate electrode in a gate trench and a gate insulating layer between a portion of the gate electrode outside the low dielectric region and the gate trench, and wherein an air gap is disposed between a portion of the gate electrode within the low dielectric region and the gate trench.

### CROSS-REFERENCE TO RELATED APPLICATION

This application claims the benefit of Korean Patent Application No. 10-2018-0166412, filed on Dec. 20, 2018, in the Korean Intellectual Property Office, the disclosure of which is incorporated herein in its entirety by reference.

### BACKGROUND

Exemplary embodiments of the inventive concept relates to a memory device, and more particularly, to a memory device including a buried word line structure.

As the degree of integration of memory devices increases, electrical characteristics of memory devices may deteriorate. For example, a memory device may include a first buried gate structure designed to be connected to a first memory cell and a second buried gate structure designed to be connected to a second memory cell. Ideally, the second buried gate structure should not affect the first memory cell. However, due to an increase in the degree of integration of the memory device, the second buried gate structure may affect the first memory cell. As a result, electrical characteristics of the memory device may deteriorate.

### SUMMARY

The inventive concept provides a memory device having improved electrical characteristics.

According to an aspect of the inventive concept, there is provided a memory device including: a substrate including a first active region and a second active region spaced apart from each other; a device isolation film on the substrate, the device isolation film defining the first active region and the second active region; and a buried word line structure passing a low dielectric region between the first active region and the second active region, wherein the buried word line structure includes a gate electrode in a gate trench and a gate insulating layer between a portion of the gate electrode outside the low dielectric region and the gate trench, and wherein an air gap is disposed between a portion of the gate electrode within the low dielectric region and the gate trench.

According to another aspect of the inventive concept, there is provided a memory device including: a substrate including a first active region and a second active region spaced apart from each other; a device isolation film on the substrate, the device isolation film defining the first active region and the second active region; a first buried word line structure passing the first active region; a second buried word line structure passing a first low dielectric region between the first active region and the second active region; and a third buried word line structure passing the second active region, wherein the first buried word line structure includes a first gate electrode in a first gate trench and a first gate insulating layer between the first gate electrode and the first gate trench, wherein the second buried word line structure includes a second gate electrode in a second gate trench, a second gate insulating layer between the second gate electrode and the second gate trench, and either a first low dielectric layer or an air gap between a portion of the second gate electrode within the first low dielectric region and the second gate trench, wherein the third buried word line structure includes a third gate electrode in a third gate trench and a third gate insulating layer between the third gate electrode and the third gate trench, and wherein a dielectric constant of the first low dielectric layer is less than a dielectric constant of the first gate insulating layer, a dielectric constant of the second gate insulating layer, and a dielectric constant of the third gate insulating layer.

According to another aspect of the inventive concept, there is provided a memory device including: a substrate including a first active region and a second active region spaced apart from each other in a first direction; a device isolation film on the substrate, the device isolation film defining the first active region and the second active region; a first buried word line structure passing the first active region; a second buried word line structure passing a first low dielectric region between the first active region and the second active region; and a third buried word line structure passing the second active region, wherein the first buried word line structure includes a first gate electrode in a first gate trench and a first gate insulating layer between the first gate electrode and the first gate trench, wherein the second buried word line structure includes a second gate electrode in a second gate trench and a second gate insulating layer between a portion of the second gate electrode outside the first low dielectric region and the second gate trench, wherein the third buried word line structure includes a third gate electrode in a third gate trench and a third gate insulating layer between the third gate electrode and the third gate trench, and wherein a first air gap is disposed between a portion of the second gate electrode within the first low dielectric region and the second gate trench.

### BRIEF DESCRIPTION OF THE DRAWINGS

Embodiments of the inventive concept will be more clearly understood from the following detailed description taken in conjunction with the accompanying drawings in which:

FIG. 1 is a plan view of a memory device according to an embodiment;

FIG. 2 is cross-sectional views of the memory device, taken along lines I-I′, II-II′, and of FIG. 1, respectively, according to example embodiments;

FIG. 3 is cross-sectional views of buried word line structures, taken along lines A-A′ and B-B′ of FIG. 1, respectively, according to example embodiments;

FIG. 4 is cross-sectional views of buried word line structures included in a memory device, according to an embodiment;

FIG. 5 is cross-sectional views of buried word line structures included in a memory device, according to an embodiment;

FIG. 6 is cross-sectional views of buried word line structures included in a memory device, according to an embodiment;

FIG. 7 is cross-sectional views of buried word line structures included in a memory device, according to an embodiment;

FIGS. 8A to 8E are cross-sectional views of a method of manufacturing buried word line structures included in a memory device, according to an embodiment;

FIGS. 9A and 9B are cross-sectional views of a method of manufacturing buried word line structures included in a memory device, according to an embodiment; and

FIGS. 10A to 10C are cross-sectional views of a method of manufacturing buried word line structures included in a memory device, according to an embodiment.

### DETAILED DESCRIPTION OF THE EMBODIMENTS

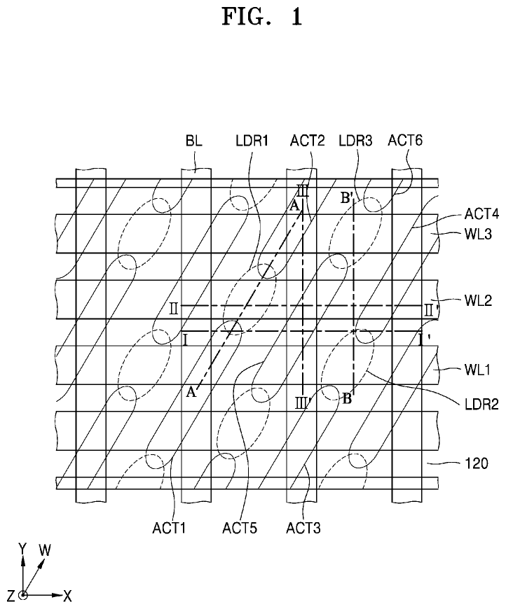

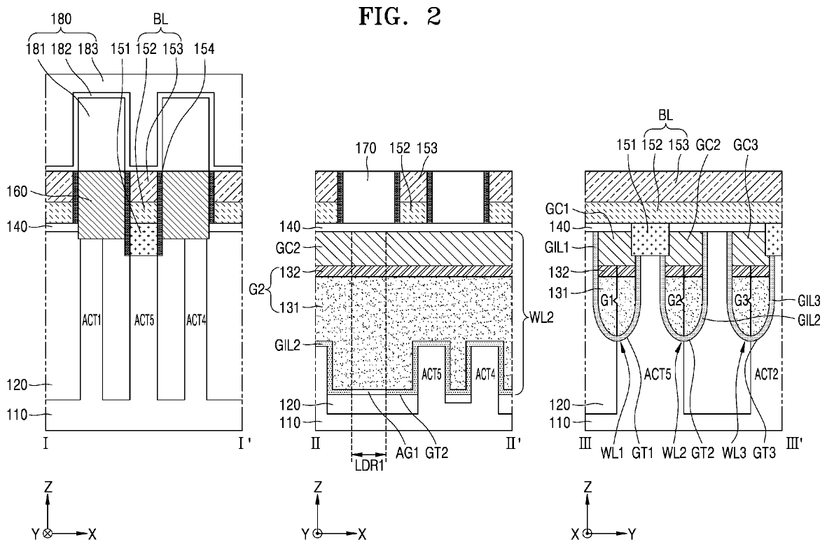

FIG. 1 is a plan view of a memory device according to an embodiment. FIG. 2 is cross-sectional views of the memory device, taken along lines I-I′, and of FIG. 1, respectively, according to example embodiments.

Referring to FIGS. 1 and 2, the memory device may include a substrate 110 having a plurality of active regions including, for example, first to sixth active regions ACT1 to ACT6, a device isolation film 120 defining the plurality of active regions, a plurality of buried word line structures including, for example, first to third buried word line structures WL1 to WL3, a plurality of bit line structures BL, and a plurality of information storage units 180.

The substrate 110 may include a semiconductor material such as a Group IV semiconductor material, a Group III-V semiconductor material, or a Group II-VI semiconductor material. The Group IV semiconductor material may include, for example, silicon (Si), germanium (Ge), or silicon (Si)-germanium (Ge). The Group III-V semiconductor material may include, for example, gallium arsenide (GaAs), indium phosphide (InP), gallium phosphide (GaP), indium arsenide (InAs), indium antimonide (InSb), or indium gallium arsenide (InGaAs). The Group II-VI semiconductor material may include, for example, zinc telluride (ZnTe) or cadmium sulfide (CdS). The substrate 110 may include a bulk wafer or an epitaxial layer.

A buffer insulating layer 140 may be disposed on the substrate 110. The buffer insulating layer 140 may include silicon oxide, silicon nitride, or a combination thereof

Active regions, for example, the first to sixth active regions ACT1 to ACT6, may have a major axis in a fourth direction (W) inclined with respect to a first direction (direction X) and a second direction (direction Y) and vertical with respect to a third direction (direction Z). The first active region ACT1 and the second active region ACT2 may be spaced from each other in the fourth direction (W), the third active region ACT3 and the fourth active region ACT4 may be spaced from each other in the fourth direction (W), and the fifth active region ACT5 and the sixth active region ACT6 may be spaced from each other in the fourth direction (W).

A low dielectric region, for example, first to third low dielectric regions LDR1 to LDR3, may be disposed between any two active regions spaced from each other in a major axis direction of active regions, for example, the fourth direction (W). For example, the first low dielectric region LDR1 may be disposed between the first active region ACT1 and the second active region ACT2, the second low dielectric region LDR2 may be disposed between the third active region ACT3 and the fourth active region ACT4, and the third low dielectric region LDR3 may be disposed between the fifth active region ACT5 and the sixth active region ACT6.

In some examples, each of the first to third low dielectric regions LDR1 to LDR3 may overlap a portion of each of corresponding two active regions in the fourth direction (W).

The device isolation film 120 defining the active regions may include, for example, silicon oxide, silicon nitride, or a combination thereof. In some embodiments, the device isolation film 120 may include a plurality of layers.

The plurality of buried word line structures including the first to third buried word line structures WL1 to WL3 may each extend in the first direction (direction X) and may be spaced from each other in the second direction (direction Y).

Each buried word line structure may pass active regions. For example, the first buried word line structure WL1 may pass the first active region ACT1 and the fifth active region ACTS, the second buried word line structure WL2 may pass the fifth active region ACTS and the fourth active region ACT4, and the third buried word line structure WL3 may pass the second active region ACT2 and the fourth active region ACT4.

Respective buried word line structures may pass low dielectric regions. For example, the first buried word line structure WL1 may pass the second low dielectric region LDR2, the second buried word line structure WL2 may pass the first low dielectric region LDR1, and the third buried word line structure WL3 may pass the third low dielectric region LDR3.

Each buried word line structure may include a gate insulating layer, a gate electrode, and a gate capping layer in a gate trench. For example, the first buried word line structure WL1 may include a first gate electrode G1 in a first gate trench GT1, a first gate insulating layer GIL1 between a portion of the first gate electrode G1 outside low dielectric regions (for example, the second low dielectric region LDR2) and the first gate trench GT1, and a first gate capping layer GC1 on the first gate electrode G1. The second buried word line structure WL2 may include a second gate electrode G2 in a second gate trench GT2, a second gate insulating layer GIL2 between a portion of the second gate electrode G2 outside low dielectric regions (for example, the first low dielectric region LDR1) and the second gate trench GT2, and a second gate capping layer GC2 on the second gate electrode G2. The third buried word line structure WL3 may include a third gate electrode G3 in a third gate trench GT3, a third gate insulating layer GIL3 between a portion of the third gate electrode G3 outside low dielectric regions (for example, the third low dielectric region LDR3) and the third gate trench GT3, and a third gate capping layer GC3 on the third gate electrode G3. In some embodiments, a gate electrode such as the first to third gate electrodes G1 to G3 may include a lower gate electrode layer 131 and an upper gate electrode layer 132 having different work functions from each other, in other embodiments, the gate electrode may instead be only a single layer. In some embodiments, the lower gate electrode layer 131 may include a plurality of layers, in other embodiments, the lower gate electrode layer 131 may instead be only a single layer.

Each of the gate insulating layers GIL1 to GIL3 may have a high-k dielectric material (“k” refers to a dielectric constant) including one or more of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, but the invention is not limited thereto.

An air gap may be disposed between a portion of the gate electrode within a low dielectric region and the gate trench. For example, referring to the cross-section, a first air gap AG1 may be disposed between a portion of the second gate electrode G2 within the first low dielectric region LDR1 and the second gate trench GT2.

In some examples, the air gap may refer to an empty space, an empty portion, or an empty region.

In some examples, the air gap may be filled with air, another gas, or a mixture thereof. Herein, a dielectric constant of each of the air, another gas, and the mixture thereof may be less than a dielectric constant of each of the gate insulating layers GIL1 to GIL3. The plurality of bit line structures BL may each extend over the buffer insulating layer 140 in the second direction (direction Y) and may be spaced from each other in the first direction (direction X). Each of the plurality of bit line structures BL may include a bit line conductive layer 152 and a bit line capping layer 153. In some embodiments, the bit line conductive layer 152 may include a plurality of laminated layers. The bit line conductive layer 152 of each of the plurality of bit line structures BL may be connected to active regions via bit line contact structures 151. For example, referring to the III-III′ cross-section, the bit line conductive layer 152 of a bit line structure BL is connected to the fifth active region ACT5 and the second active region ACT2 via two bit line contact structures 151. A bit line contact structure 151 may be referred to as a direct contact (DC).

Two side walls of each of the plurality of bit line structures BL may be covered by bit line spacers 154. An interlayer insulating layer 170 may fill a space between bit line structures BL. The interlayer insulating layer 170 may include silicon oxide, silicon nitride, or a combination thereof.

Each of the plurality of information storage units 180 may be connected to an active region via an information storage unit contact structure 160. For example, referring to the I-I′ cross-section, an information storage unit 180 may be connected to the first active region ACT1, and another information storage unit 180 may be connected to the fourth active region ACT4. The information storage unit contact structure 160 may include a buried contact BC and a landing pad LP. The plurality of information storage units 180 may be, for example, a plurality of capacitors. The plurality of capacitors may include a lower electrode 181, a dielectric layer 182, and an upper electrode 183. In some embodiments, the plurality of information storage units 180 may share the upper electrode 183 and the dielectric layer 182. For example, the plurality of information storage units 180 may include a plurality of lower electrodes 181, the dielectric layer 182, and the upper electrode 183.

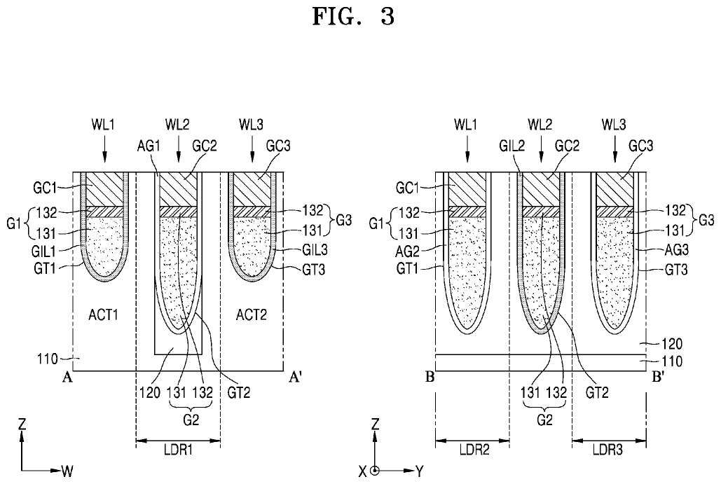

FIG. 3 is cross-sectional views of buried word line structures, taken along lines A-A′ and B-B′ of FIG. 1, respectively, according to example embodiments.

Referring to FIGS. 1 and 3, the substrate 110 includes the first active region ACT1 and the second active region ACT2 spaced from each other. The device isolation film 120 defines the first active region ACT1 and the second active region ACT2. The first buried word line structure WL1 passes the first active region ACT1 and passes the second low dielectric region LDR2. The second buried word line structure WL2 passes the first low dielectric region LDR1 between the first active region ACT1 and the second active region ACT2 and passes between the second low dielectric region LDR2 and the third low dielectric region LDR3. The third buried word line structure WL3 passes the second active region ACT2 and passes the third low dielectric region LDR3.

The first buried word line structure WL1 includes the first gate electrode G1 in the first gate trench GT1, the first gate insulating layer GIL1 between a portion of the first gate electrode G1 outside the second low dielectric region LDR2 and the first gate trench GT1, and the first gate capping layer GC1 on the first gate electrode G1. A second air gap AG2 is disposed between a portion of the first gate electrode G1 within the second low dielectric region LDR2 and the first gate trench GT1.

The second buried word line structure WL2 includes the second gate electrode G2 in the second gate trench GT2, the second gate insulating layer GIL2 between a portion of the second gate electrode G2 outside the first low dielectric region LDR1 and the second gate trench GT2, and the second gate capping layer GC2 on the second gate electrode G2. The first air gap AG1 is disposed between a portion of the second gate electrode G2 within the first low dielectric region LDR1 and the second gate trench GT2.

The third buried word line structure WL3 includes the third gate electrode G3 in the third gate trench GT3, the third gate insulating layer GIL3 between a portion of the third gate electrode G3 outside the third low dielectric region LDR3 and the third gate trench GT3, and the third gate capping layer GC3 on the third gate electrode G3. A third air gap AG3 is disposed between a portion of the third gate electrode G3 within the third low dielectric region LDR3 and the third gate trench GT3.

At least a portion of the first air gap AG1 is disposed between the device isolation film 120 and the second gate electrode G2. At least a portion of the first air gap AG1 is disposed between the first active region ACT1 and the second gate electrode G2 or between the second active region ACT2 and the second gate electrode G2. At least a portion of the first air gap AG1 is disposed between the second gate trench GT2 and the second gate capping layer GC2. For example, a portion of the second gate capping layer GC2 within the first low dielectric region LDR1 is spaced from the second gate trench GT2 due to the first air gap AG1.

Since the first air gap AG1 has a dielectric constant (e.g., “k”) less than that of the second gate insulating layer GIL2, the first air gap AG1 may decrease an influence of the second buried word line structure WL2 on the first active region ACT1 and the second active region ACT2. As described above, a memory device according to an embodiment may include an air gap and thus may decrease an influence of a buried word line structure passing between two active regions on the two active regions. Accordingly, electrical characteristics of the memory device, for example, read/write characteristics and refresh characteristics, may improve.

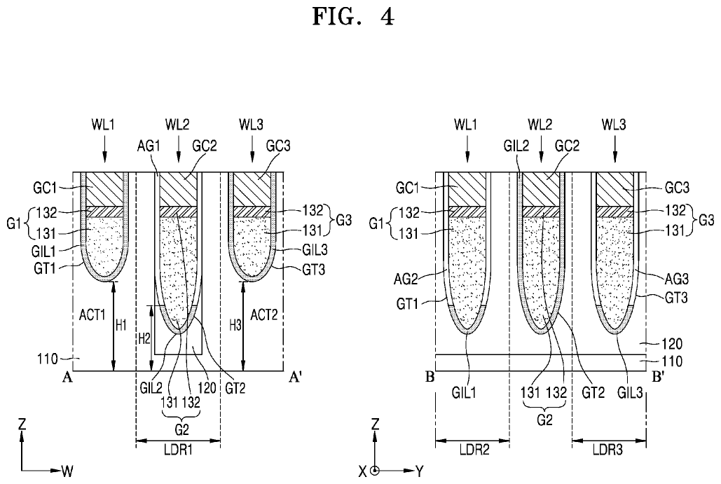

FIG. 4 is cross-sectional views of buried word line structures included in a memory device, according to an embodiment. Hereinafter, differences between buried word line structures shown in FIG. 3 and buried word line structures shown in FIG. 4 will be described.

Referring to FIG. 4, the first gate insulating layer GIL1 may fill a space between a lower portion of a portion of the first gate electrode G1 within the second low dielectric region LDR2 and the first gate trench GT1. For example, the second air gap AG2 may not be disposed between a lower portion of the first gate electrode G1 within the second low dielectric region LDR2 and the first gate trench GT1. The second air gap AG2 may be disposed between an upper portion of the first gate electrode G1 within the second low dielectric region LDR2 and the first gate trench GT1. The second gate insulating layer GIL2 may fill a space between a lower portion of a portion of the second gate electrode G2 within the first low dielectric region LDR1 and the second gate trench GT2. For example, the first air gap AG1 may not be disposed between a lower portion of the second gate electrode G2 within the first low dielectric region LDR1 and the second gate trench GT2. The first air gap AG1 may be disposed between an upper portion of the second gate electrode G2 within the first low dielectric region LDR1 and the second gate trench GT2. The third gate insulating layer GIL3 may fill a space between a lower portion of the third gate electrode G3 within the third low dielectric region LDR3 and the third gate trench GT3. For example, the third air gap AG3 may not be disposed between a lower portion of the third gate electrode G3 within the third low dielectric region LDR3 and the third gate trench GT3. The third air gap AG3 may be disposed between an upper portion of the third gate electrode G3 within the third low dielectric region LDR3 and the third gate trench GT3.

In addition, with respect to a cross-sectional view of buried word line structures taken along line A-A′, a height H2 from a lower surface of the substrate 110 to a lower end of the first air gap AG1 within the first low dielectric region LDR1 may be less than a height H1 from the lower surface of the substrate 110 to a lower end of the first gate insulating layer GIL1 within the first active region ACT1 and a height H3 from the lower surface of the substrate 110 to a lower end of the third gate insulating layer GIL3 within the second active region ACT2.

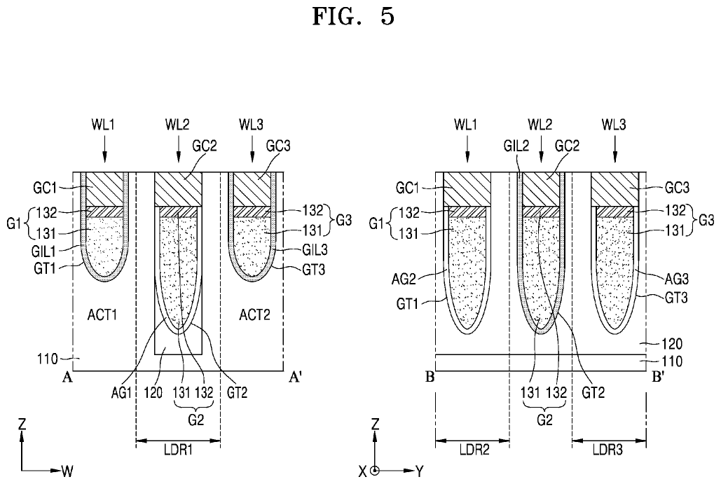

FIG. 5 is cross-sectional views of buried word line structures included in a memory device, according to an embodiment. Hereinafter, differences between buried word line structures shown in FIG. 3 and buried word line structures shown in FIG. 5 will be described.

Referring to FIG. 5, a portion of the second gate capping layer GC2 within the first low dielectric region LDR1 may contact the second gate trench GT2. The term “contact,” or “in contact with” as used herein refers to a direct connection (i.e., touching) unless the context indicates otherwise. For example, the portion of the second gate capping layer GC2 within the first low dielectric region LDR1 directly connects to the second gate trench GT2. A portion of the first gate capping layer GC1 within the second low dielectric region LDR2 may contact the first gate trench GT1. A portion of the third gate capping layer GC3 within the third low dielectric region LDR3 may contact the third gate trench GT3. For example, the first air gap AG1 may not be disposed between the second gate capping layer GC2 within the first low dielectric region LDR1 and the second gate trench GT2. The second air gap AG2 may not be disposed between the first gate capping layer GC1 within the second low dielectric region LDR2 and the first gate trench GT1. The third air gap AG3 may not be disposed between the third gate capping layer GC3 within the third low dielectric region LDR3 and the third gate trench GT3.

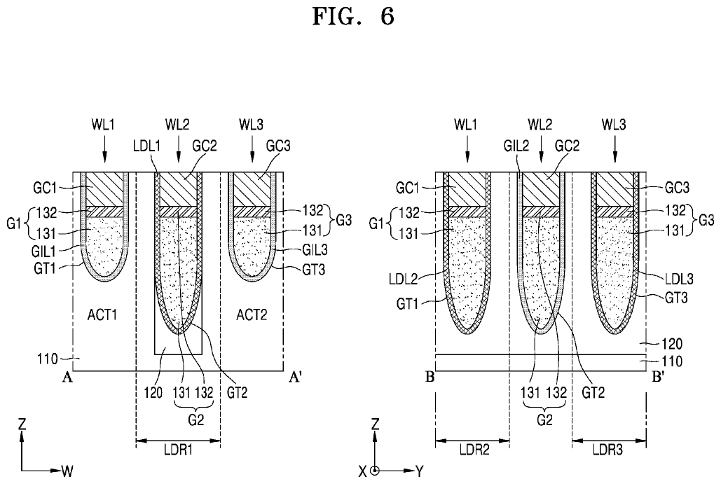

FIG. 6 is cross-sectional views of buried word line structures included in a memory device, according to an embodiment. Hereinafter, differences between buried word line structures shown in FIG. 3 and buried word line structures shown in FIG.6 will be described.

Referring to FIG. 6, the second buried word line structure WL2 may include a first low dielectric layer LDL1 between a portion of the second gate electrode G2 within the first low dielectric region LDR1 and the second gate trench GT2. A dielectric constant of the first low dielectric layer LDL1 may be less than a dielectric constant of the first gate insulating layer GIL1, a dielectric constant of the second gate insulating layer GIL2, and a dielectric constant of the third gate insulating layer GIL3.

In some examples, the first low dielectric layer LDL1 may have a low-k dielectric material including one or more of flowable oxide (FOX), tonen silazene (TOSZ), undoped silica glass (USG), borosilica glass (BSG), phosphosilica glass (PSG), borophosphosilica glass (BPSG), plasma enhanced tetraethyl orthosilicate (PETEOS), fluoride silicate glass (FSG), carbon doped silicon oxide (CDO), xerogel, aerogel, amorphous fluorinated carbon, organo silicate glass (OSG), parylene, bis-benzocyclobutenes (BCB), SiLK, polyimide, and porous polymeric material, but not limited thereto.

The first buried word line structure WL1 may include a second low dielectric layer LDL2 between a portion of the first gate electrode G1 within the second low dielectric region LDR2 and the first gate trench GT1. A dielectric constant of the second low dielectric layer LDL2 may be less than the dielectric constant of the first gate insulating layer GILL the dielectric constant of the second gate insulating layer GIL2, and the dielectric constant of the third gate insulating layer GIL3.

The third buried word line structure WL3 may include a third low dielectric layer LDL3 between a portion of the third gate electrode G3 within the third low dielectric region LDR3 and the third gate trench GT3. A dielectric constant of the third low dielectric layer LDL3 may be less than the dielectric constant of the first gate insulating layer GIL1, the dielectric constant of the second gate insulating layer GIL2, and the dielectric constant of the third gate insulating layer GIL3.

In example embodiments, each of the first, second and third low dielectric layers LDL1, LDL2 and LDL3 may be the same material as each other.

Since the first low dielectric layer LDL1 has a dielectric constant less than that of the second gate insulating layer GIL2, the first low dielectric layer LDL1 may decrease an influence of the second buried word line structure WL2 on the first active region ACT1 and the second active region ACT2. As described above, a memory device according to an embodiment may include a low dielectric layer and thus may decrease an influence of a buried word line structure passing between two active regions on the two active regions. Accordingly, electrical characteristics of the memory device, for example, read/write characteristics and refresh characteristics, may improve.

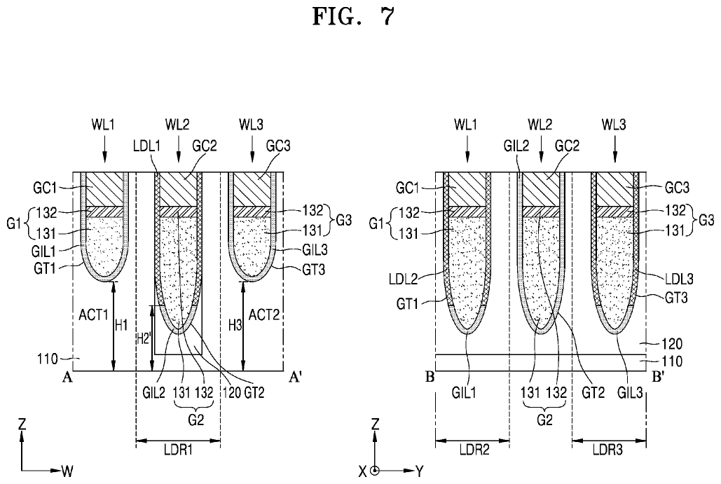

FIG. 7 is cross-sectional views of buried word line structures included in a memory device, according to an embodiment. Hereinafter, differences between buried word line structures shown in FIG. 6 and buried word line structures shown in FIG. 7 will be described.

Referring to FIG. 7, the first gate insulating layer GIL1 may fill a space between a lower portion of a portion of the first gate electrode G1 within the second low dielectric region LDR2 and the first gate trench GT1. For example, the second low dielectric layer LDL2 may not be disposed between a lower portion of the first gate electrode G1 within the second low dielectric region LDR2 and the first gate trench GT1. The second low dielectric layer LDL2 may be disposed between an upper portion of the first gate electrode G1 within the second low dielectric region LDR2 and the first gate trench GT1. In addition, the second gate insulating layer GIL2 may fill a space between a lower portion of a portion of the second gate electrode G2 within the first low dielectric region LDR1 and the second gate trench GT2. For example, the first low dielectric layer LDL1 may not be disposed between a lower portion of the second gate electrode G2 within the first low dielectric region LDR1 and the second gate trench GT2. The first low dielectric layer LDL1 may be disposed between an upper portion of the second gate electrode G2 within the first low dielectric region LDR1 and the second gate trench GT2. In addition, the third gate insulating layer GIL3 may fill a space between a lower portion of a portion of the third gate electrode G3 within the third low dielectric region LDR3 and the third gate trench GT3. For example, the third low dielectric layer LDL3 may not be disposed between a lower portion of the third gate electrode G3 within the third low dielectric region LDR3 and the third gate trench GT3. The third low dielectric layer LDL3 may be disposed between an upper portion of the third gate electrode G3 within the third low dielectric region LDR3 and the third gate trench GT3.

With respect to a cross-sectional view of buried word line structures taken along line A-A′, a height H2′ from a lower surface of the substrate 110 to a lower end of the first low dielectric layer LDL1 within the first low dielectric region LDR1 may be less than the height H1 from the lower surface of the substrate 110 to a lower end of a portion of the first gate insulating layer GIL1 within the first active region ACT1 and the height H3 from the lower surface of the substrate 110 to a lower end of a portion of the third gate insulating layer GIL3 within the second active region ACT2.

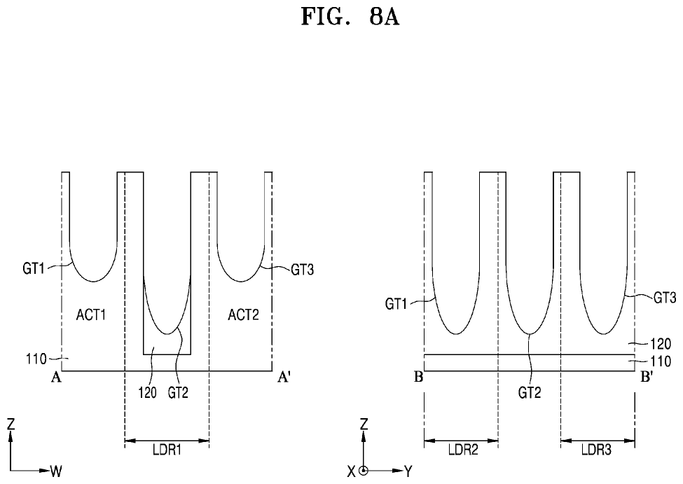

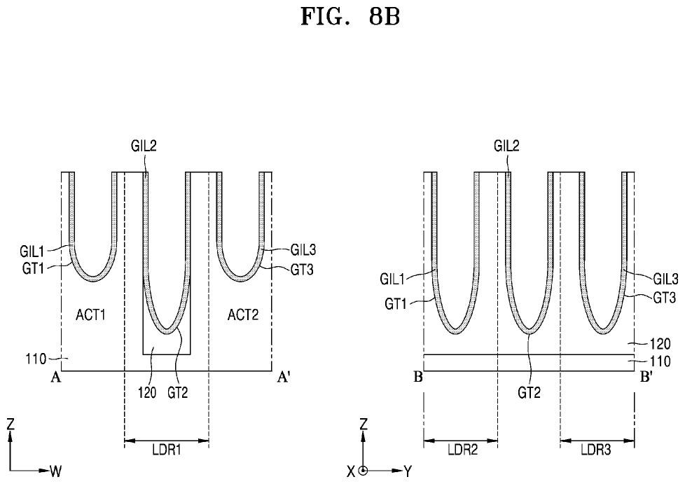

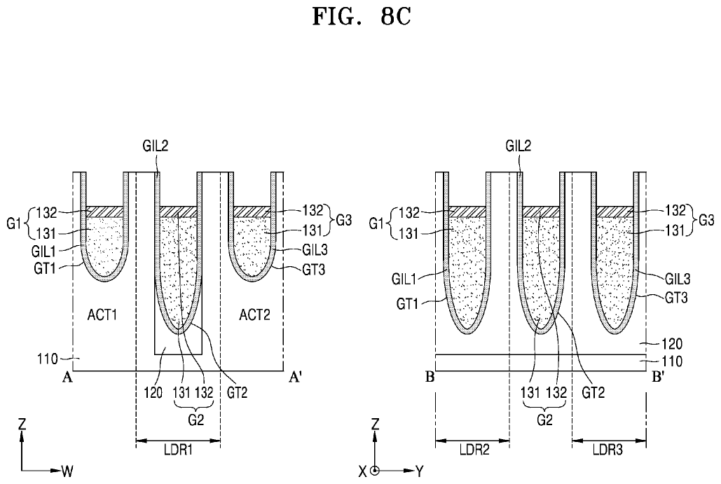

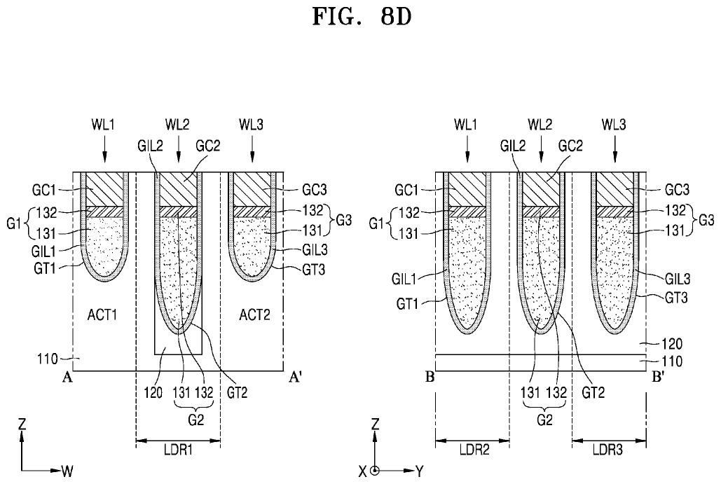

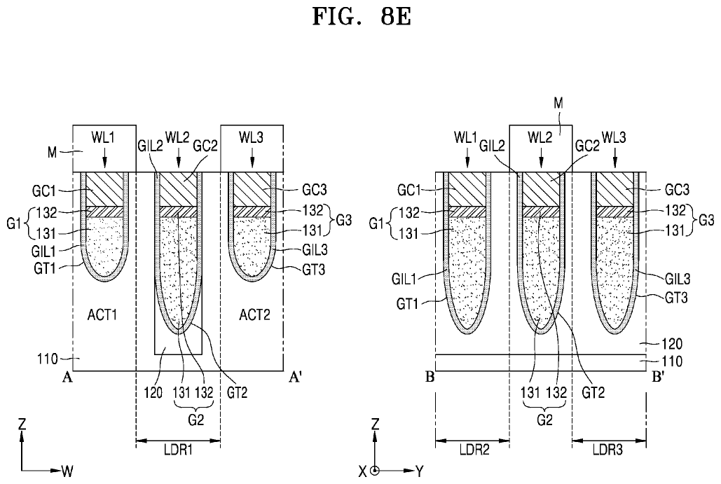

FIGS. 8A to 8E are cross-sectional views of a method of manufacturing buried word line structures included in a memory device, according to an embodiment.

Referring to FIG. 8A, the device isolation film 120 defining a plurality of active regions including the first active region ACT1 and the second active region ACT2 in the substrate 110 may be formed. A plurality of source/drain regions may be formed by injecting impurities to an upper surface of the plurality of active regions including the first active region ACT1 and the second active region ACT2. Next, a plurality of gate trenches including the first gate trench GT1, the second gate trench GT2, and the third gate trench GT3 may be formed.

Referring to FIG. 8B, a gate insulating layer may be formed on an inner wall of the plurality of gate trenches. For example, the first gate insulating layer GIL1 may be formed on the first gate trench GT1, the second gate insulating layer GIL2 may be formed on the second gate trench GT2, and the third gate insulating layer GIL3 may be formed on the third gate trench GT3.

Referring to FIG. 8C, a plurality of gate electrodes including the first to third gate electrodes G1 to G3 may be formed. Each gate electrode may be formed in a gate trench and may fill at least a portion of the gate trench. For example, the lower gate electrode layer 131 may be formed on the first gate insulating layer GILL the second gate insulating layer GIL2, and the third gate insulating layer GIL3 and may be etched back later. Next, the upper gate electrode layer 132 may be formed on the lower gate electrode layer 131 and may be etched back later.

Referring to FIG. 8D, a plurality of gate capping layers including the first to third gate capping layers GC1 to GC3 may be formed. Each gate capping layer may be on a gate electrode and may fill an upper portion of the gate trench. A gate capping layer (not shown) may be formed on the plurality of gate electrodes including the first to third gate electrodes G1 to G3 and may be etched back.

Referring to FIG. 8E, a mask M exposing a plurality of low dielectric regions including the first to third low dielectric regions LDR1 to LDR3 may be formed on the substrate 110. Next, the gate insulating layer within a low dielectric region may be etched. For example, the second gate insulating layer GIL2 within the first low dielectric region LDR1, the first gate insulating layer GIL1 within the second low dielectric region LDR2, and the third gate insulating layer GIL3 within the third low dielectric region LDR3 may be etched. When the gate insulating layer within each of the low dielectric regions is entirely etched, buried word line structures shown in FIG. 3 may be formed. When only an upper portion of the gate insulating layer within each of the low dielectric regions is etched, buried word line structures shown in FIG. 4 may be formed.

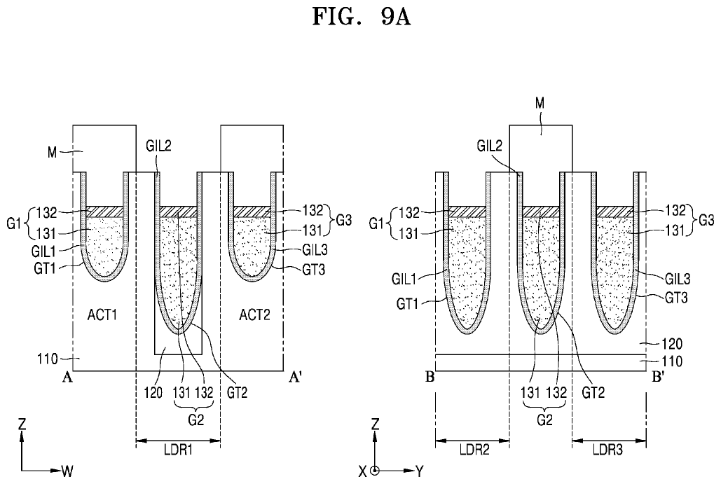

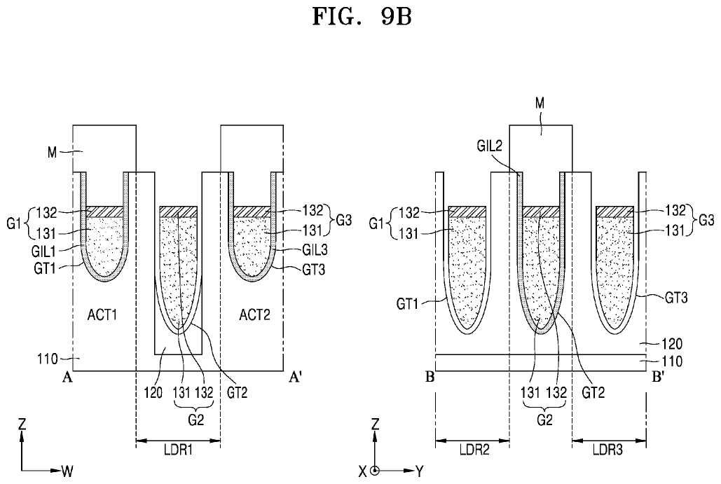

FIGS. 9A and 9B are cross-sectional views of a method of manufacturing buried word line structures included in a memory device, according to an embodiment.

After the processes shown in FIGS. 8A to 8C are performed, a process shown in FIG. 9A may be performed. Referring to FIG. 9A, the mask M exposing a plurality of low dielectric regions including the first to third low dielectric regions LDR1 to LDR3 may be formed on the substrate 110.

Referring to FIG. 9B, a gate insulating layer within a low dielectric region may be etched. For example, the second gate insulating layer GIL2 within the first low dielectric region LDR1, the first gate insulating layer GIL1 within the second low dielectric region LDR2, and the third gate insulating layer GIL3 within the third low dielectric region LDR3 may be etched. The gate insulating layer within each of the low dielectric regions may be entirely etched as shown in FIG. 9B. In some embodiments, only an upper portion of the gate insulating layer within each of the low dielectric regions may be etched.

Next, referring to FIG. 5, a plurality of gate capping layers including the first to third gate capping layers GC1 to GC3 may be formed. Thus, buried word line structures shown in FIG. 5 may be manufactured.

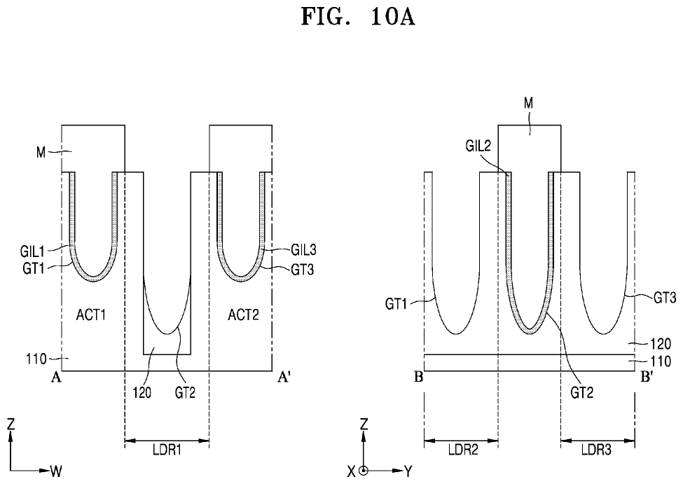

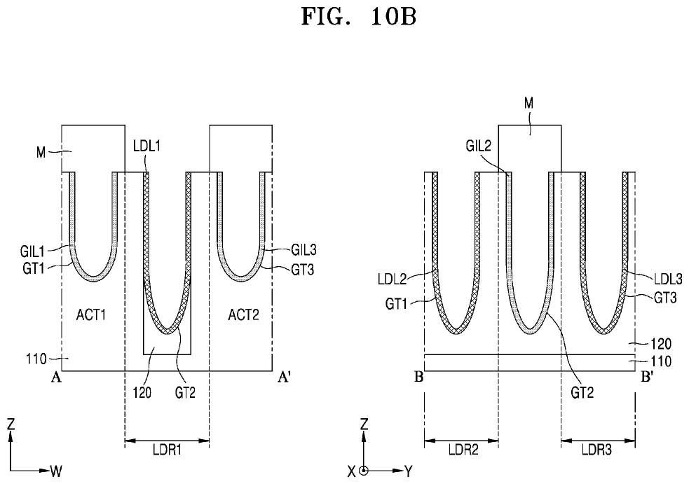

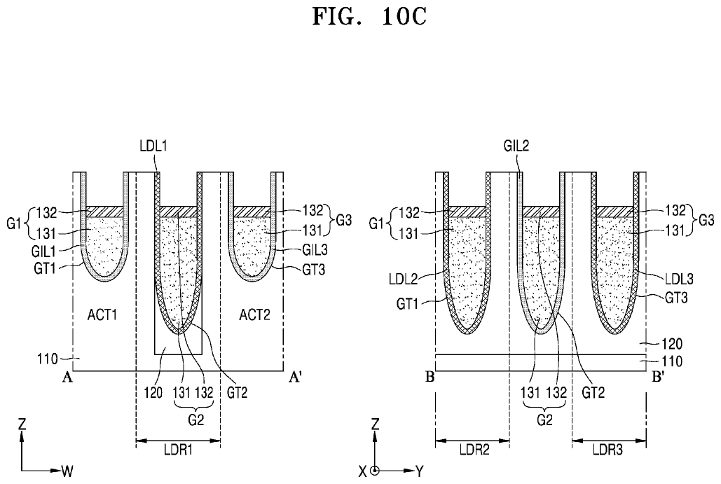

FIGS. 10A to 10C are cross-sectional views of a method of manufacturing buried word line structures included in a memory device, according to an embodiment.

After the processes shown in FIGS. 8A and 8B are performed, a process shown in FIG. 10A may be performed. Referring to FIG. 10A, the mask M exposing a plurality of low dielectric regions including the first to third low dielectric regions LDR1 to LDR3 may be formed on the substrate 110. A gate insulating layer within a low dielectric region may be etched. For example, the second gate insulating layer GIL2 within the first low dielectric region LDR1, the first gate insulating layer GIL1 within the second low dielectric region LDR2, and the third gate insulating layer GIL3 within the third low dielectric region LDR3 may be etched.

Referring to FIG. 10B, a low dielectric layer may be formed on a portion of a gate trench within each of the low dielectric regions. For example, the first low dielectric layer LDL1 may be formed on a portion of the second gate trench GT2 within the first low dielectric region LDR1, the second low dielectric layer LDL2 may be formed on a portion of the first gate trench GT1 within the second low dielectric region LDR2, and the third low dielectric layer LDL3 may be formed on a portion of the third gate trench GT3 within the third low dielectric region LDR3.

Referring to FIG. 10C, a plurality of gate electrodes may be formed in a plurality of gate trenches. For example, the first gate electrode G1 may be formed in the first gate trench GT1, the second gate electrode G2 may be formed in the second gate trench GT2, and the third gate electrode G3 may be formed in the third gate trench GT3.

Referring to FIG. 6, a plurality of gate capping layers may be formed in the plurality of gate trenches. For example, the first gate capping layer GC1 may be formed in the first gate trench GT1, the second gate capping layer GC2 may be formed in the second gate trench GT2, and the third gate capping layer GC3 may be formed in the third gate trench GT3. Thus, buried word line structures shown in FIG. 6 may be formed.

When, during the process shown in FIG. 10A, only an upper portion of each gate insulating layer within each of the low dielectric regions is removed, and a lower portion of each gate insulating layer within each of the low dielectric regions is left, buried word line structures shown in FIG. 7 may be formed.

While the inventive concept has been particularly shown and described with reference to embodiments thereof, it will be understood that various changes in form and details may be made therein without departing from the spirit and scope of the following claims.

What is claimed is:

1. A memory device comprising:
a substrate comprising a first active region and a second active region spaced apart from each other;
a device isolation film on the substrate, the device isolation film defining the first active region and the second active region; and
a buried word line structure passing a low dielectric region between the first active region and the second active region,
wherein the buried word line structure comprises a gate electrode in a gate trench and a gate insulating layer between a portion of the gate electrode outside the low dielectric region and the gate trench, and
wherein an air gap is disposed between a portion of the gate electrode within the low dielectric region and the gate trench.

2. The memory device of claim 1, wherein the gate insulating layer fills a space between a lower portion of the portion of the gate electrode within the low dielectric region and the gate trench.

3. The memory device of claim 1, wherein at least a portion of the air gap is disposed between the device isolation film and the gate electrode.

4. The memory device of claim 1, wherein at least a portion of the air gap is disposed between the first active region and the gate electrode or between the second active region and the gate electrode.

5. The memory device of claim 1, further comprising a gate capping layer on the gate electrode.

6. The memory device of claim 5, wherein a portion of the gate capping layer within the low dielectric region is spaced apart from the gate trench due to the air gap.

7. The memory device of claim 5, wherein a portion of the gate capping layer within the low dielectric region contacts the gate trench.

8. The memory device of claim 7, wherein a portion of the gate capping layer outside the low dielectric region is spaced apart from the gate trench due to the gate insulating layer.

9. The memory device of claim 1, wherein each of the first active region and the second active region has a major axis in a first direction, and
wherein the first active region and the second active region are spaced apart from each other in the first direction with the low dielectric region therebetween.

10. A memory device comprising:
a substrate comprising a first active region and a second active region spaced apart from each other;
a device isolation film on the substrate, the device isolation film defining the first active region and the second active region;
a first buried word line structure passing the first active region;
a second buried word line structure passing a first low dielectric region between the first active region and the second active region; and
a third buried word line structure passing the second active region,
wherein the first buried word line structure comprises a first gate electrode in a first gate trench and a first gate insulating layer between the first gate electrode and the first gate trench,
wherein the second buried word line structure comprises a second gate electrode in a second gate trench, a second gate insulating layer between the second gate electrode and the second gate trench, and a first low dielectric layer between a portion of the second gate electrode within the first low dielectric region and the second gate trench,
wherein the third buried word line structure comprises a third gate electrode in a third gate trench and a third gate insulating layer between the third gate electrode and the third gate trench, and
wherein a dielectric constant of the first low dielectric layer is less than a dielectric constant of each of the first gate insulating layer, the second gate insulating layer, and the third gate insulating layer.

11. The memory device of claim 10, wherein the second gate insulating layer fills a space between a lower portion of the second gate electrode within the first low dielectric region and the second gate trench.

12. The memory device of claim 11, wherein a height from a lower surface of the substrate to a lower end of the first low dielectric layer is less than a height from the lower surface of the substrate to a lower end of the first gate insulating layer within the first active region and is less than a height from the lower surface of the substrate to a lower end of the third gate insulating layer within the second active region.

13. The memory device of claim 10, wherein the first low dielectric layer contacts at least one of the first active region and the second active region.

14. The memory device of claim 13, wherein the first low dielectric layer contacts the device isolation film.

15. The memory device of claim 10, wherein the first buried word line structure passes a second low dielectric region spaced apart from the first low dielectric region,
wherein the third buried word line structure passes a third low dielectric region spaced apart from the first low dielectric region and the second low dielectric region, and
wherein the second buried word line structure passes between the second low dielectric region and the third low dielectric region.

16. The memory device of claim 15, wherein the first buried word line structure further comprises a second low dielectric layer between a portion of the first gate electrode within the second low dielectric region and the first gate trench,
wherein the third buried word line structure further comprises a third low dielectric layer between a portion of the third gate electrode within the third low dielectric region and the third gate trench, and
wherein a dielectric constant of each of the second low dielectric layer and the third low dielectric layer is less than the dielectric constant of each of the first gate insulating layer, the second gate insulating layer, and the third gate insulating layer.

17. A memory device comprising:
a substrate comprising a first active region and a second active region spaced apart from each other in a first direction;
a device isolation film on the substrate, the device isolation film defining the first active region and the second active region;
a first buried word line structure passing the first active region;
a second buried word line structure passing a first low dielectric region between the first active region and the second active region; and
a third buried word line structure passing the second active region,
wherein the first buried word line structure comprises a first gate electrode in a first gate trench and a first gate insulating layer between the first gate electrode and the first gate trench,
wherein the second buried word line structure comprises a second gate electrode in a second gate trench and a second gate insulating layer between a portion of the second gate electrode outside the first low dielectric region and the second gate trench,
wherein the third buried word line structure comprises a third gate electrode in a third gate trench and a third gate insulating layer between the third gate electrode and the third gate trench, and
wherein a first air gap is disposed between a portion of the second gate electrode within the first low dielectric region and the second gate trench.

18. The memory device of claim 17, wherein the second gate insulating layer fills a space between a lower portion of the second gate electrode within the first low dielectric region and the second gate trench.

19. The memory device of claim 18, wherein a height from a lower surface of the substrate to a lower end of the first air gap is less than a height from the lower surface of the substrate to a lower end of the first gate insulating layer within the first active region and a height from the lower surface of the substrate to a lower end of the third gate insulating layer within the second active region.

20. The memory device of claim 17, wherein the first buried word line structure passes a second low dielectric region between a third active region and a fourth active region spaced apart from each other in the first direction,
wherein the third buried word line structure passes a third low dielectric region between a fifth active region and a sixth active region spaced apart from each other in the first direction,
wherein the second buried word line structure passes between the second low dielectric region and the third low dielectric region,
wherein a second air gap is disposed between a portion of the first gate electrode within the second low dielectric region and the first gate trench, and
wherein a third air gap is disposed between a portion of the third gate electrode within the third low dielectric region and the third gate trench.
